(19) United States
(12) Patent Application Publication
(10) Pub. No.: US 2026/0147958 A1
(43) Pub. Date: May 28, 2026

(54) METHODS OF TUNING CHIMES AND AUDIBLE CHIMES FORMED THEREBY

(71) Applicant: Purdue Research Foundation, West Lafayette, IN (US)

(72) Inventors: Richard Mark French, West Lafayette, IN (US); Therese Bernadette Malinowski, Downers Grove, IL (US)

(21) Appl. No.: 19/397,048

(22) Filed: Nov. 21, 2025

Related U.S. Application Data
(60) Provisional application No. 63/724,693, filed on Nov. 25, 2024.

(51) Int. Cl. G06F 30/20; B33Y 10/00; G10D 13/06

(52) U.S. Cl. CPC G06F 30/20; G10D 13/06; B33Y 10/00

(57) ABSTRACT

Audible chimes, methods of tuning a chime, and chimes produced by such methods. In such a method, a digital model of a chime having a beam is created. The model is used to calculate locations for changes to the cross-section of the beam to attain pre-selected resonant frequencies, such as a series. The beam may then be modified in the manner calculated to have the changes to the cross-section at the locations identified by the calculations.

### CROSS-REFERENCE TO RELATED APPLICATIONS

This application claims the benefit of provisional U.S. patent application Ser. No. 63/724,693 filed Nov. 25, 2024, the contents of which are incorporated herein by reference.

### BACKGROUND OF THE INVENTION

The invention generally relates to chimes. More particularly, the invention relates to audible chimes, methods of tuning chimes, and chimes produced in accordance with such methods.

Current designs of grandfather clock chimes and musical tube chimes are tuned to a primary note but produce inharmonic overtone frequencies. It is highly desirable for instruments to produce harmonics, and therefore these inharmonic overtone frequencies are typically perceived as sounding undesirably dissonant to listeners.

It would be desirable if a method existed by which a chime could be tuned to remove dissonance over the entire audible frequency spectrum of the chime and/or produce other target resonant frequencies.

### BRIEF SUMMARY OF THE INVENTION

The intent of this section of the specification is to briefly indicate the nature and substance of the invention, as opposed to an exhaustive statement of all subject matter and aspects of the invention. Therefore, while this section identifies subject matter recited in the claims, additional subject matter and aspects relating to the invention are set forth in other sections of the specification, particularly the detailed description, as well as any drawings.

The present invention provides, but is not limited to, audible chimes, methods of tuning chimes, and chimes produced by such methods.

According to a nonlimiting aspect of the invention, a method is provided for tuning a chime having a beam with resonant frequencies of about 20 Hz to about 20,000 Hz that are elements of a harmonic series. The method includes creating a computerized model of the beam, modeling masses on the computerized model of the beam, each mass on the computerized model being located at a selected node along a length of the computerized model of the beam, simulating harmonic frequencies produced by the computerized model of the beam with the masses on the computerized model as a function of mass and inertia properties of the computerized model of the beam, identifying locations and masses along a length of the beam that attain a harmonic series using an optimization method and the harmonic frequencies produced by the computerized model of the beam, and modifying the beam to have at least one tuning mass at at least one of the locations identified along the length of the beam.

According to another nonlimiting aspect, an audible chime having a beam with resonant frequencies of about 20 Hz to about 20,000 Hz that are elements of a harmonic series is created in accordance with a method as described above.

According to yet another nonlimiting aspect, a method is provided for tuning a chime comprising an elongate beam having a length extending from a first end to a second end. A desired set of target resonant frequencies to be produced by the chime is selected. One or more changes to the beam at a corresponding one or more identified locations along the length are calculated that are mathematically predicted to cause the chime to produce the desired set of target resonant frequencies. The beam may then be modified to include one or more of the calculated changes at the identified locations.

According to a further nonlimiting aspect, an audible chime having a beam with resonant frequencies of about 20 Hz to about 20,000 Hz that are elements of the desired set of target resonant frequencies created in accordance with a method as described above.

Technical aspects of methods and chimes as described above preferably include the ability to provide a chime that is able to generate tones and overtones in a harmonic series, ideally so as to attain a more pleasant audible sound than conventional chimes.

These and other aspects, arrangements, features, and/or technical effects will become apparent upon detailed inspection of the figures and the following description.

### BRIEF DESCRIPTION OF THE DRAWINGS

FIG. 1 is a diagrammatic representation of a chime having a cantilever beam and a chime having a freely supported beam.

FIG. 2 illustrates steps in a method according to an embodiment of the invention.

FIG. 3 illustrates steps in another method according to an embodiment of the invention.

FIG. 4 is a schematic representation of a chime having a cantilever beam according to an embodiment of the invention.

FIG. 5 illustrates steps in yet another method according to an embodiment of the invention.

FIG. 6 shows a tubular chime according to an embodiment of the invention.

FIG. 7 shows another tubular chime according to an embodiment of the invention.

FIG. 8 is a computer code listing for making calculations according to an embodiment of the invention.

FIG. 9 is another computer code listing for making calculations according to an embodiment of the invention.

### DETAILED DESCRIPTION OF THE INVENTION

The intended purpose of the following detailed description of the invention and the phraseology and terminology employed therein is to describe what is shown in the drawings, which include the depiction of and/or relate to one or more nonlimiting embodiments of the invention, and to describe certain but not all aspects of what is depicted in the drawings, including the embodiment(s) to which the drawings relate. The following detailed description also describes certain investigations relating to the embodiment(s) depicted in the drawings, and identifies certain but not all alternatives of the embodiment(s). As nonlimiting examples, the invention encompasses additional or alternative embodiments in which one or more features or aspects shown and/or described as part of a particular embodiment could be eliminated, and also encompasses additional or alternative embodiments that combine two or more features or aspects shown and/or described as part of different embodiments. Therefore, the appended claims, and not the detailed description, are intended to particularly point out subject matter regarded to be aspects of the invention, including certain but not necessarily all of the aspects and alternatives described in the detailed description.

As used herein the terms “a” and “an” to introduce a feature are used as open-ended, inclusive terms to refer to at least one, or one or more of the features, and are not limited to only one such feature unless otherwise expressly indicated. Similarly, use of the term “the” in reference to a feature previously introduced using the term “a” or “an” does not thereafter limit the feature to only a single instance of such feature unless otherwise expressly indicated.

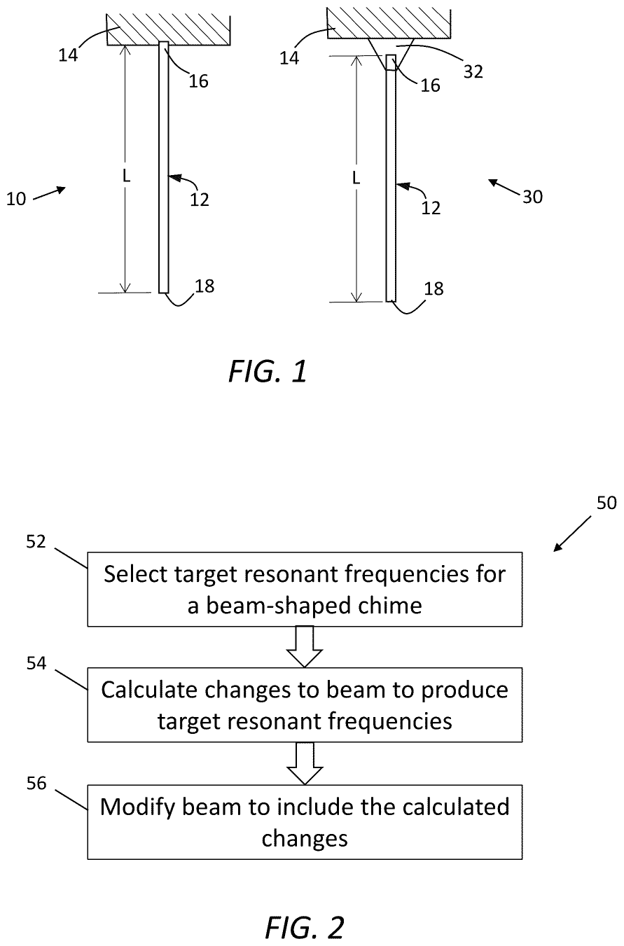

Turning now to the nonlimiting embodiments represented in the drawings, FIG. 1 illustrates examples of two types of beam-type chimes for which methods disclosed herein can be used: a chime 10 configured as a cantilever beam 12 with a single “free” end 18 free to move and with the opposite end being a “fixed” end 16 that is rigidly fixed to a structure 14, and a chime 30 configured as a freely supported beam 12 with opposite ends 16 and 18 that are both free to move though with one end 16 supported (e.g., suspended) with a support element 32, as nonlimiting examples, a hanger, wire, hook, chain, chord, string, or similar structure that allows the end 16 to vibrate. As used herein, the term “beam” is used to refer to not only cantilever and freely supported beams, in that chimes can also be pinned. Cantilever, freely supported, and pinned beams have particular boundary conditions for vibration beams, and methods described herein apply equally well to boundary conditions associated with cantilever, freely supported, and pinned beams. The chimes 10 and 30 may be, by way of nonlimiting examples, a chime for a clock or a musical instrument.

As noted above, the chime 10 represented in FIG. 1 is fundamentally a cantilever beam 12 extending from the support structure 14. The beam 12 extends from the proximal fixed end 16 rigidly secured to the support structure 14, and terminates at the distal free end 18. The fixed end 16 is fixed to and constrained by the support structure 14 so that it cannot oscillate freely. The free end 18 is not fixed to any support structure and is unconstrained so that it can oscillate freely. Further, the length L of the beam 12 between the fixed end 16 and the free end 18 is also not attached to any structures so as also to be able to freely oscillate. An example of such a chime 10 is a typical clock chime.

As also noted above, the chime 30 represented in FIG. 1 is fundamentally a freely supported beam 12 that is supported such that both ends 16 and 18 are free ends that can oscillate freely. The upper free end 16 of the chime 30 is shown as supported (e.g., suspended) from the support 32 so that the upper end 16 is free to vibrate. An example of such a chime 30 is a typical orchestral tube chime.

The beams 12 represented in FIG. 1 and encompassed by the following disclosure may be solid beams, such as bars or rods, or hollow beams, such as hollow tubes. Typically, though not necessarily, the beams 12 have a substantially uniform cross-sectional shape along their entire lengths L. For example, the beams 12 may be hollow straight cylindrical tubes or solid straight cylindrical or rectangular rods, though other shapes could be used. The chimes 10 and 30 are provided solely as examples for discussion; and the methods for tuning chimes disclosed herein are not limited to use with these particular examples of chimes, but may be used to tune other types of beam-type chimes.

FIG. 2 illustrates a method 50 for tuning a beam-type chime, such as either of the chimes 10 and 30, shown configured as elongate beams 12 that are adapted to emit a desired set of resonant frequencies when struck. Typically, such a beam 12 has known physical properties, such as length, shape, diameter and/or other width dimensions, material, and boundary conditions, such as whether the beam 12 is a fixed-free beam (e.g., chime 10) or a free-free beam (e.g., chime 30). Other physical characteristics may also be known. At 52, the desired set of target resonant frequencies is identified. For example, the target set of resonant frequencies may be a set of harmonic frequencies, though other sets of resonant frequencies may be selected. Next, at 54, one or more changes to the beam 12 at a corresponding number of identified locations along the length of the beam 12 are calculated that are mathematically predicted to cause the chime to produce the desired set of target resonant frequencies. The calculation may be made, for example, by using a mathematical model of the beam 12 based on its physical properties with one or more structural modeling algorithms such as computer structural analysis software to analyze the resonance properties of the beam 12 and calculate various modifications to the beam 12 to provide the desired target resonant frequencies of the chime. At 56, based on the calculated modifications, the beam 12 itself can be modified to include at least one and preferably all of the calculated changes at the calculated locations. For example, the calculated changes may include modifying the cross-section of the beam 12 at various identified locations along the length of the beam 12 by, for example, adding mass to the beam 12, removing mass from the beam 12, and/or changing the shape(s) of one or more sidewalls the beam 12 in the case of a tube-shaped or otherwise hollow beam. The method 100 can be used to tune the chime 10 to have resonant frequencies in the typical audible range for humans that are elements of an octave harmonic series, other harmonic series, and/or other sets of resonant frequencies.

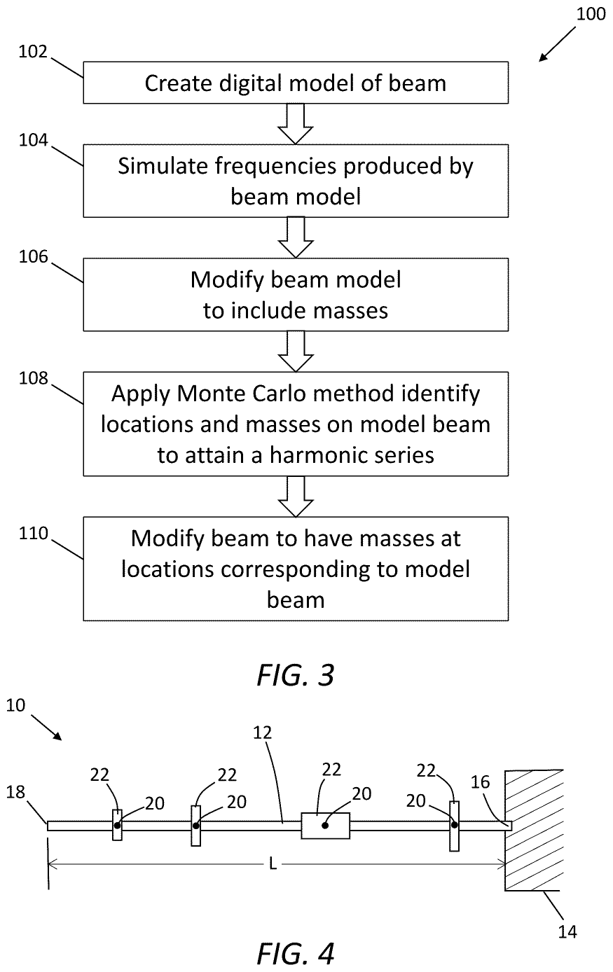

Turning to FIGS. 3 and 4, a nonlimiting example of a method 100 is described that uses an optimization method and an additive process to tune a chime according to the present invention is described. Though the chime is represented in FIG. 4 as the same or similar to the chime 10 represented in FIG. 1 having a cantilever beam 12, the method is also applicable to other types of beams including freely supported and pinned beams as previously discussed. In this case, the method 100 uses a Monte Carlo simulation as the optimization method, though those skilled in the art will be aware that other optimization methods could have been used. In FIG. 3, the method 100 is represented by which the chime 10 of FIG. 4 can be tuned to produce a harmonic series by adding tuning masses 22 at locations along the length L of the beam 12. In one embodiment, the harmonic series achieved is a harmonic series in which the resonant frequencies are integer multiples of the fundamental resonant frequency. The method 100 can be used to tune the chime 10 to have resonant frequencies in the typical audible range for humans (generally considered to be about 20 Hz to about 20,000 Hz) that are elements of an octave harmonic series.

The method 100 uses structural optimization to tune the beam 12 by treating it as an inverse spectral problem. The method 100 creates a harmonic series by the deliberate design of masses at specific locations along the length L of the beam 12. The method 100 includes simulating the frequencies produced by the beam 12 as a function of its mass and inertia properties, identifying locations (e.g., nodes) 20 on the beam 12 where additional mass is needed to create the desired harmonic series, and then modifying the beam 12 to include tuning masses 22 at those locations 20, as schematically represented in FIG. 4. As depicted in FIG. 4, such masses 22 may be effectively point masses located along the length L of the beam 12, though the method also encompasses distributed masses 22 added to the beam 12. For example, one of the tuning masses 22 is represented in FIG. 4 as a distributed mass 22, which can be configured as a tube that is slid over a limited portion the exterior of the beam 12 to add mass over a selected limited length portion of the beam 12 that may encompass one or more selected nodes of the beam 12, such that each such mass 22 does not behave as a point mass but instead increases the mass of the beam 12 and distributes that mass over the selected node(s) where the mass 22 will be located.

The process is then inverted to produce locations 20 and tuning masses 22 needed to attain a harmonic series using an optimization (e.g., Monte Carlo) method. In one embodiment of the method 100, at 102 a mathematical (e.g., computerized) model (beam model) of the beam 12 is created. Next, the mathematical model is used to calculate locations (nodes) 20 where one or more tuning mass 22 are to be added to the beam 12 to produce a preselected set of resonant frequencies using the optimization method. For example, at 104, one or more masses are modeled on the beam model. As represented in FIG. 4, the modeled masses are depicted as individually located at selected nodes along the length of the beam model corresponding to the length L of the beam 12. At 106, the harmonic frequencies produced by the beam model are simulated with the one or more modeled masses as a function of mass and inertia properties. At 108, results from the simulation are used to identify the location and mass for each tuning mass 22 to be placed on the beam 12 to attain the harmonic series using the optimization method. At 110, the beam 12 can then be modified to have the mass(es) 22 added at the location(s) (nodes) identified by the beam model and simulations.

Various methods are possible for modifying the beam 12 as described above. For example, weights can be added to the chime 10 to change its resonant frequencies. As a particular example, the beam 12 can be modified by attaching weights thereto at the locations used and/or identified in the beam model along the length of the beam 12 to change the resonant frequencies of the beam 12 to be in a harmonic series, such as the octave harmonic series. This approach modifies the mass distribution of the beam 12 but does not significantly affect its stiffness along its length L. As another example, weight can be removed from the chime 10 to change its resonant frequencies. As a particular example, the cross-sectional area of the beam 12 can be modified to alter its mass and/or stiffness by changing the cross-sectional area of the beam 12 at selected locations along its length L corresponding to the locations and masses used and/or identified in the beam model to change the resonant frequencies of the beam 12 to occur in the harmonic series. For example, if the beam 12 has a solid rectangular cross section extending from the fixed (proximal) end 16 to the free (distal) end 18, modification may be accomplished by modifying the height of the rectangular cross-section at one or more locations along the length L that correspond with the masses and locations used and/or identified in the beam model. In another example, if the beam 12 is formed by a hollow tube, such as having a round or rectangular cross-section that defines an outer sidewall defining a substantially constant shape from the fixed end 16 to the free end 18 of the beam 12, the wall thickness of the sidewall can be varied so that resonant frequencies are terms in a harmonic series. This will change both the mass and stiffness distributions along the length of the beam 12. For example, the cross-sectional area of a tube-shaped beam 12 may be changed by modifying the wall thickness of one or more sidewalls of the beam 12 at one or more locations along the beam length L that correspond with the masses and locations used and/or identified in the beam model.

In yet another example, a hybrid method may be implemented to modify the beam 12 that includes both changing the cross-sectional area of the beam 12 by either method outlined above and attaching weights to the beam 12 at selected locations as indicated by the beam model to attain the tuned harmonic series.

Although the different approaches to the method 100 as described above could be used for tuning a chime to almost any set of harmonics, in practical terms, it is typically only necessary to tune those in the human hearing range, which typically nominally range from about 20 Hz to about 20,000 Hz. Further, the resonant frequencies of the chime 10 do not necessarily have to include every term in a harmonic series. For example, a harmonic series starting at 110 Hz may contain the frequencies 110 Hz, 220 Hz, 330 Hz, 440 Hz, and so on. However, a chime 10 with frequencies of 110 Hz, 220 Hz, and 440 Hz would still make a pleasing, consonant sound, even though the 330 Hz component is absent.

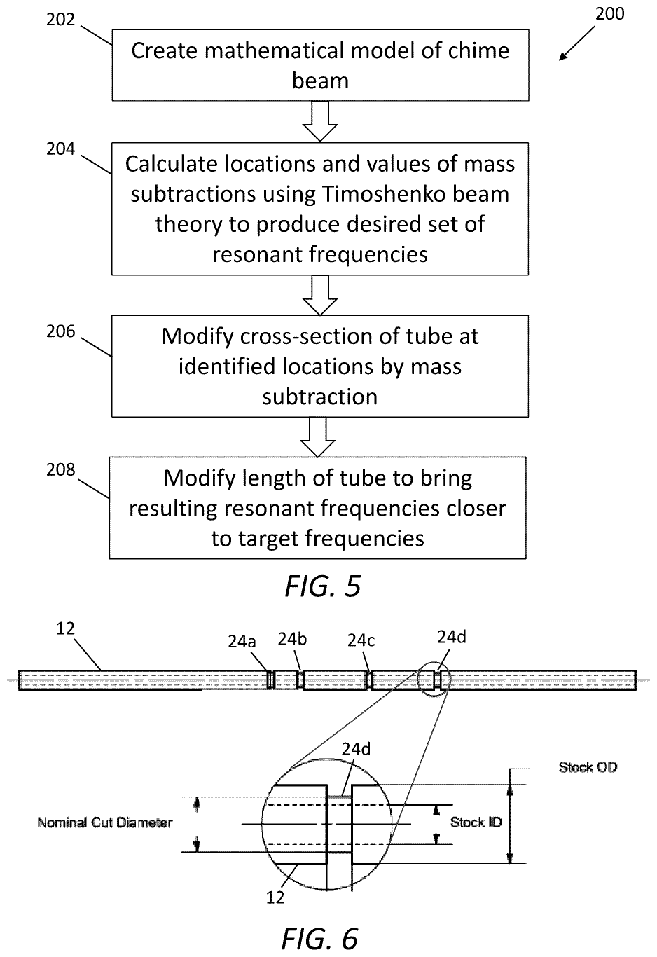

FIG. 5 illustrates another nonlimiting example method 200 of tuning a beam-type chime through mass subtraction according to further principles disclosed herein. Using such a subtractive process, a tuning mass 22 is not an additional mass added to a particular location of a beam 12 according to an additive process as described in reference to FIGS. 3 and 4, but instead is the mass that remains at a particular location on the beam 12 as a result of removing mass from the beam 12. It should be understood that both additive and subtractive processes can be performed on the same beam 12, and therefore are not mutually exclusive for the purpose of tuning a beam-type chime, for example, the chimes 10 and 30 represented in FIGS. 1 and 4.

In the following nonlimiting example, the subtractive process utilized by the method 200 is accomplished by changing the cross-section of a hollow cylindrical tubular beam 12 to be used for a chime 10 or 30. The subtractive process may include, for example, removing a portion of a sidewall of the tubular beam 12 using a lathe. Other methods of removing portions of the beam 12 may be used. At 202, a mathematical model of the beam 12 is created. The mathematical model may be developed, for example, to capture various physical characteristics of the beam 12 as described above suitable for being used by a computer software program to calculate resonant frequency information about the beam.

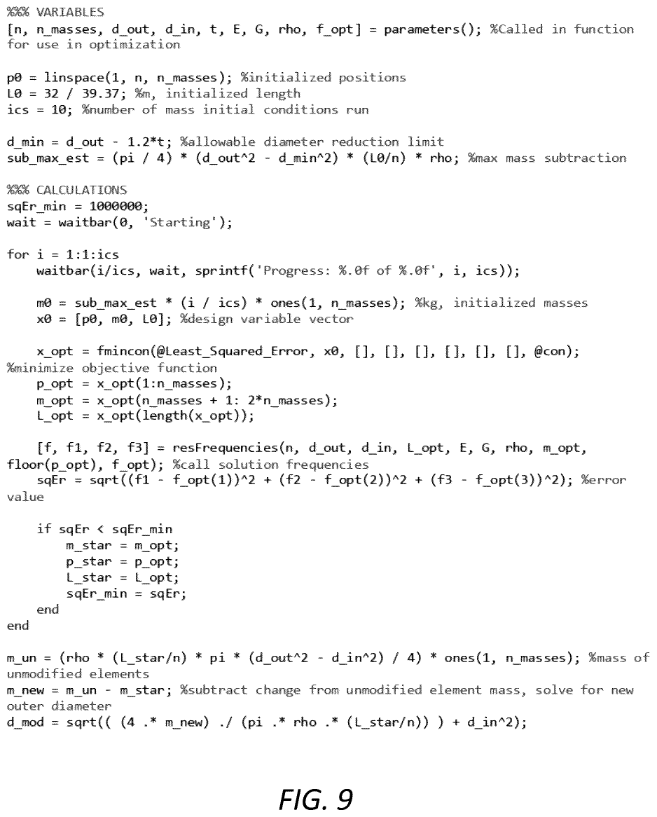

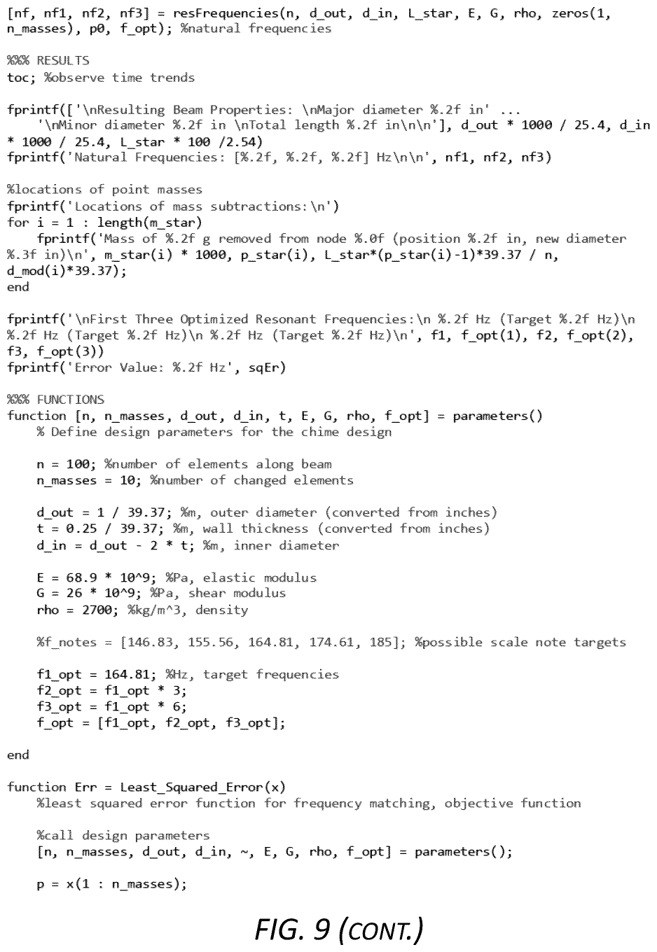

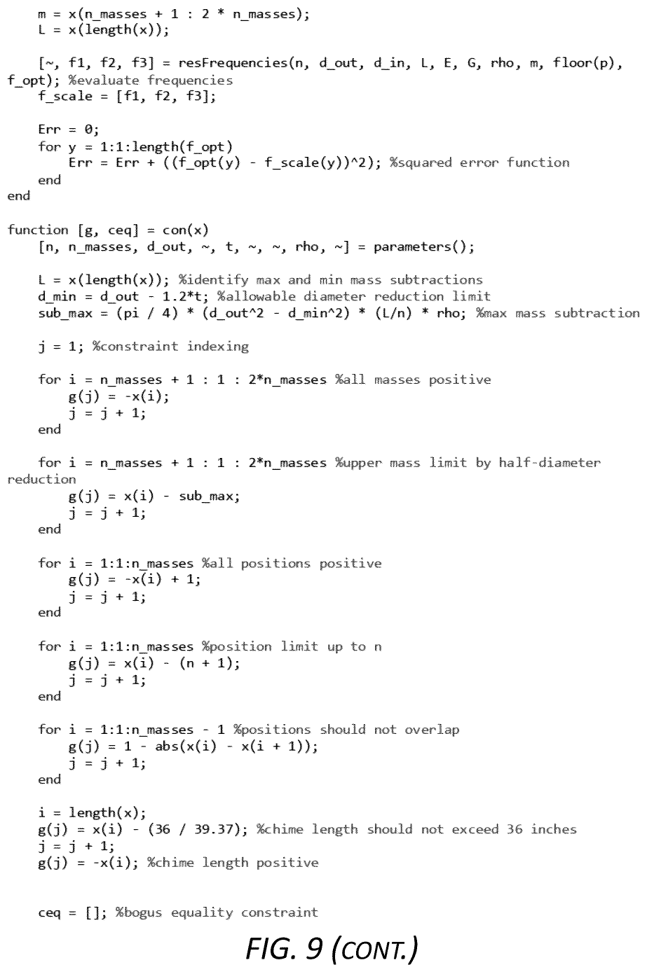

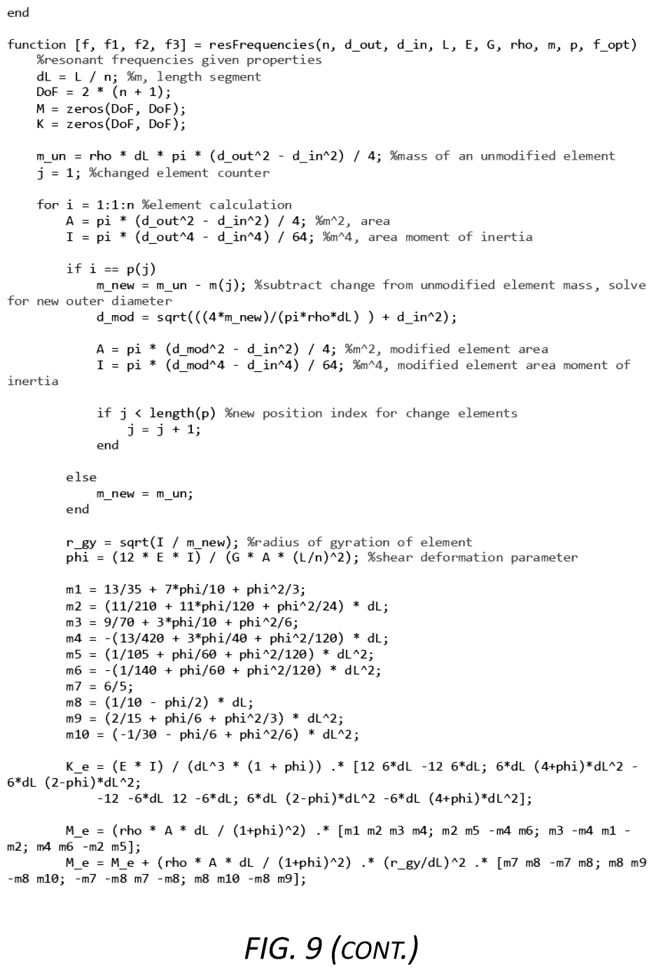

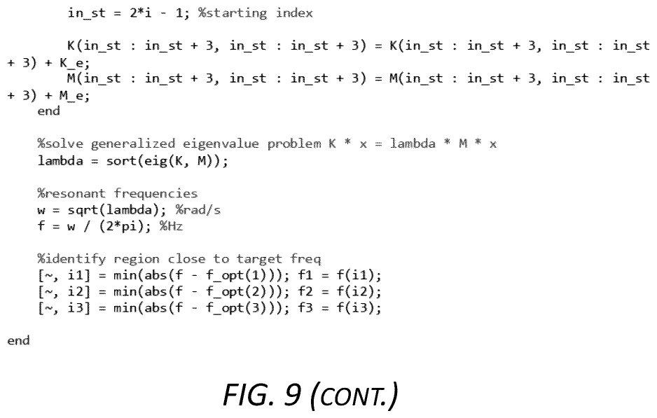

At 204, based on the mathematical model of the beam 12 the locations and values of mass subtractions are calculated designed to produce a preselected set of target resonant frequencies from the beam 12. One example set of target harmonic frequencies may be a harmonic series; however, additional or alternative target harmonic frequencies may be selected. The calculations may include using Timoshenko beam theory to analyze the mathematical model. In one example, a MATLAB algorithm using Timoshenko beam theory as shown in FIG. 9, which uses finite element analysis software code to calculate identified locations and values of mass subtractions as well as an overall design tube length for obtaining the target harmonic frequencies from the chime 10 or 30. This calculation minimizes errors between the selected target resonant frequencies (the “design frequencies”) and the actual resulting resonant frequencies when implemented on the actual beam 12. Optionally, the resulting geometry may be read into an Ansys modal analysis software program, and minor length changes may be calculated to obtain the resulting calculated resonant frequencies closer to the set of target resonant frequencies. Thus, the design/calculation steps may include calculating changes to the length of the beam 12 as another design variable.

At 206, using the calculated identified locations and values of mass subtractions, the cross-section of the tube (beam 12) can then be modified at subtracting the calculated mass values from the tube wall at the corresponding calculated locations along the length of the tube. For example, as shown in FIG. 6, mass from the beam 12 may be removed at identified locations 24a, 24b, 24, and 24d by removing material from the outer surface of the sidewall using a lathe. Thus, for example, each lathe cut may be customized as to width and/or depth to remove exactly the calculated amount of material mass from the beam 12 at the corresponding identified location. However, the mass removal may be accomplished by any other method capable of and suitable for removing the appropriate calculated mass from the beam at the identified location.

At 208, the length of the tube may optionally be modified to bring the resulting resonant frequencies closer to the design target resonant frequencies. For example, the length of the beam 12 may be shortened by removing a portion from either or both ends 16, 18 of the beam 12. This modification may be in accordance with whatever length modification was calculated during the calculation step 204.

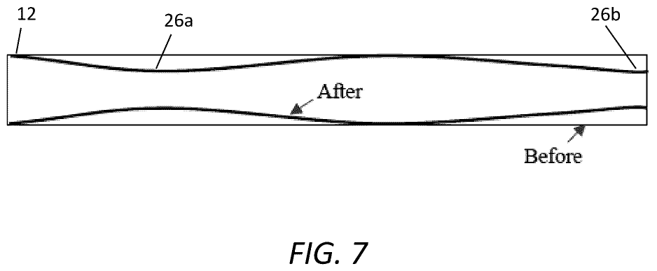

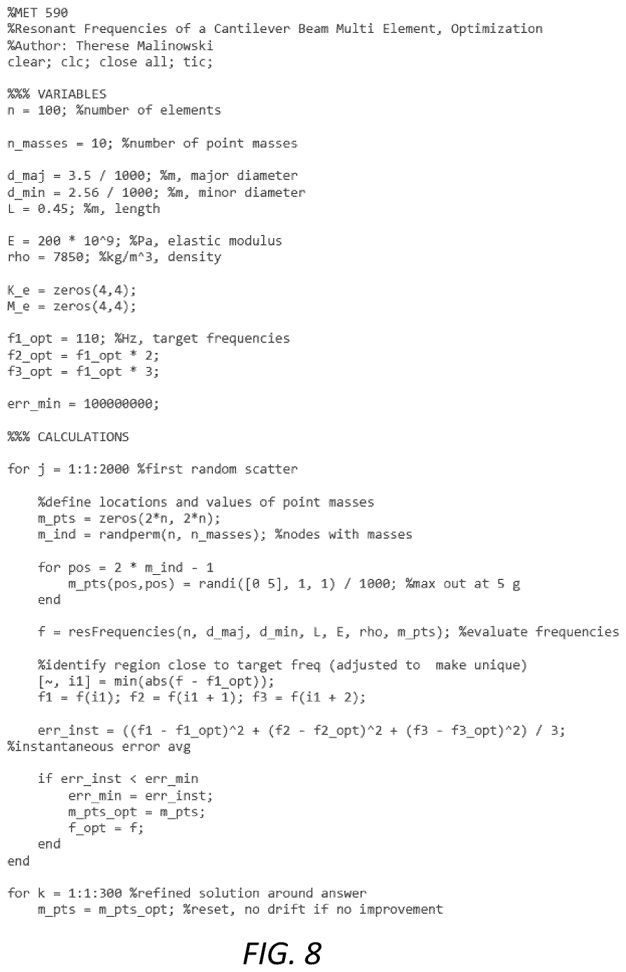

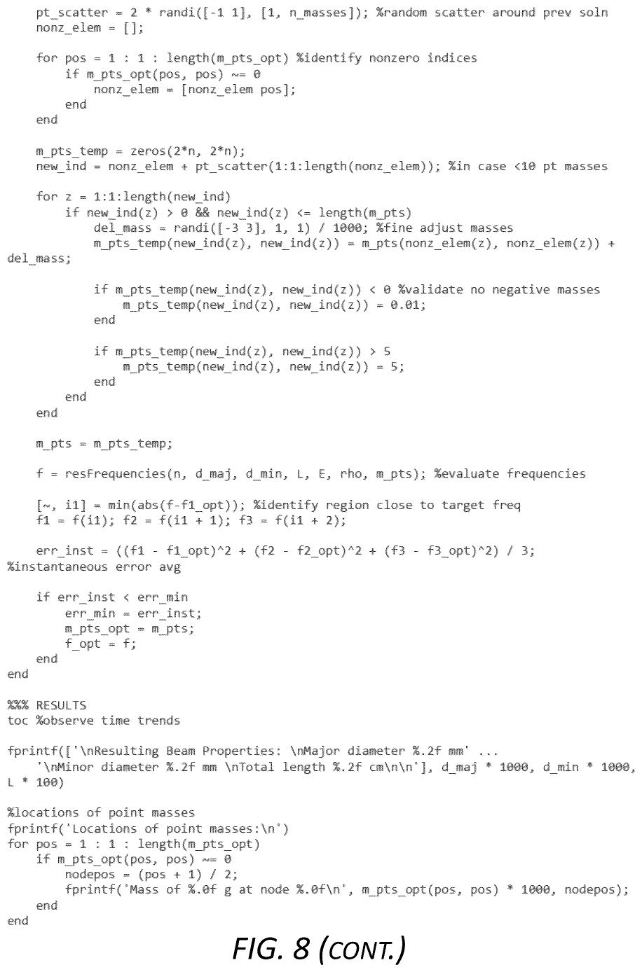

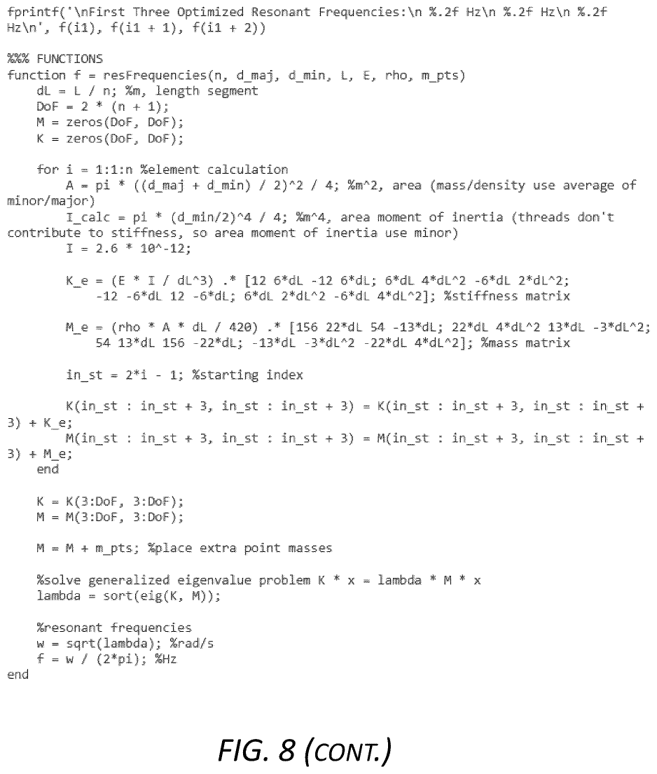

In some embodiments, another method of modifying the cross-section of the beam 12 is to modify the diameter of a hollow tube rather than adding or subtracting mass to the tube. for example, the resonant frequencies of a beam-type hollow tube chime may be tuned by selectively changing the diameter of the tube wall calculated amounts at calculated identified positions along its length without changing the wall thickness. FIG. 7 illustrates an example in which the diameter of the tube wall of an originally cylindrical hollow tube chime 12 is reduced as locations 26a and 26b. This can be performed, for example, by plastic deformation of the tube wall in any suitable manner, such as using dies, drawing, or other suitable processes.

Tests leading to the present invention have shown the practical feasibility of the methods disclosed herein to successfully tune beam-type chimes to produce such a harmonic series. Additional aspects and advantages of this invention will be further appreciated from nonlimiting embodiments, investigations, etc., described in the attached Appendix A, the contents of which are incorporated herein by reference. In particular, Appendix A describes testing and a Monte Carlo algorithm that was used as the optimization method to successfully generate values of masses and their locations along a test cantilever beam that would cause its resulting frequencies to be a harmonic series in accordance with the method 100.

The method 100 of tuning chimes as described herein enables chimes to produce an octave harmonic series. An important secondary feature is that it allows a designer to select a desired fundamental frequency. The method 100 of tuning chimes is also capable of creating a more desirable frequency spectrum by producing overtones in octaves with a root note.

As previously noted above, though the foregoing detailed description describes certain aspects of one or more particular embodiments of the invention, alternatives could be adopted by one skilled in the art. For example, the chime 10 and its components could differ in appearance and construction from the embodiments described herein and shown in the drawings, functions of certain components of the chime 10 could be performed by components of different construction but capable of a similar (though not necessarily equivalent) function, and various materials could be used in the fabrication of the chime 10 and/or its components. As such, and again as was previously noted, it should be understood that the invention is not necessarily limited to any particular embodiment described herein or illustrated in the drawings.

1. A method of tuning a chime comprising a beam to have resonant frequencies of about 20 Hz to about 20,000 Hz that are elements of a harmonic series, the method comprising:
creating a computerized model of the beam;
modeling masses on the computerized model of the beam, each mass on the computerized model being located at a selected node along a length of the computerized model of the beam;
simulating harmonic frequencies produced by the computerized model of the beam with the masses on the computerized model as a function of mass and inertia properties of the computerized model of the beam;
identifying locations and masses along a length of the beam that attain a harmonic series using an optimization method and the harmonic frequencies produced by the computerized model of the beam; and
modifying the beam to have at least one tuning mass at at least one of the locations identified along the length of the beam.

2. The method of claim 1, wherein the modifying of the beam comprises an additive process and the at least one tuning mass is obtained by adding mass to the beam at the at least one of the locations identified along the length of the beam to change the resonant frequencies of the beam to be in a harmonic series.

3. The method of claim 1, wherein the modifying of the beam comprises a subtractive process and the at least one tuning mass is obtained by removing mass from the beam at the at least one of the locations identified along the length of the beam to change the resonant frequencies of the beam to be in a harmonic series.

4. The method of claim 3, wherein the beam has a solid rectangular cross section extending from a proximal end to a distal end of the beam, and wherein the subtractive process comprises modifying the height of the rectangular cross-section at the at least one of the locations identified along the length of the beam.

5. The method of claim 3, wherein the beam comprises a hollow tube having an outer sidewall having a wall thickness and defining a substantially constant shape from a proximal end to a distal end of the beam, and wherein the subtractive process comprises modifying the wall thickness at the at least one of the locations identified along the length of the beam.

6. The method of claim 3, further comprising attaching weights to the beam at the at least one of the locations identified along the length of the beam to change the resonant frequencies of the beam.

7. The method of claim 1, wherein the at least one tuning mass is a point mass.

8. The method of claim 1, wherein the beam is a cantilever beam, a freely supported beam, or a pinned beam.

9. A method of tuning a chime, wherein the chime comprises an elongate beam having a length extending from a first end to a second end, the method comprising:
selecting a desired set of target resonant frequencies to be produced by the chime;
calculating one or more changes to the beam at a corresponding one or more identified locations along the length that are mathematically predicted to cause the chime to produce the desired set of target resonant frequencies; and
modifying the beam to include one or more of the changes at the identified locations.

10. The method of claim 9, wherein the changes include changing the mass of the beam at the identified locations.

11. The method of claim 10, wherein changing the mass comprises removing mass from the beam at least at one of the identified locations.

12. The method of claim 10, wherein the step of calculating comprises using Timoshenko beam theory to calculate the identified locations and values of mass changes at the identified locations to produce the desired set of target resonant frequencies.

13. The method of claim 10, wherein changing the mass comprises adding mass to the beam at least at one of the identified locations.

14. The method of claim 10, wherein the step of calculating comprises using an optimization method to calculate the identified locations and values of mass changes at the identified locations to produce the desired set of target resonant frequencies.

15. The method of claim 9, wherein the elongate beam comprises a hollow tube formed by a tubular wall, wherein the changes include changing a diameter of the hollow tube without changing a thickness of the tubular wall.

16. The method of claim 9, wherein modifying the beam includes changing the length of the beam.

17. The method of claim 9, wherein the set of target resonant frequencies is a harmonic series.

18. The method of claim 9, wherein the chime is a cantilever beam, a freely supported beam, or a pinned beam.

19. The method of claim 9, wherein the chime is a tubular beam with opposite ends being free to move.

20. An audible chime comprising a beam produced by the method of claim 9 to have resonant frequencies of about 20 Hz to about 20,000 Hz that are elements of the desired set of target resonant frequencies.
